(19) United States
(12) Patent Application Publication
(10) Pub. No.: US 2025/0083188 A1
(43) Pub. Date: Mar. 13, 2025

(54) ULTRASOUND TRANSDUCER WITH REDUCED CROSS-TALK AND METHOD OF MANUFACTURE

(71) Applicants: Roger Zemp, Edmonton (CA); Mohammad Rahim Sobhani, Edmonton (CA)

(72) Inventors: Roger Zemp, Edmonton (CA); Mohammad Rahim Sobhani, Edmonton (CA)

(21) Appl. No.: 18/367,387

(22) Filed: Sep. 12, 2023

(51) Int. Cl. B06B 1/06; H10N 30/06; H10N 30/088; H10N 30/87

(52) U.S. Cl. CPC B06B 1/06; H10N 30/06; H10N 30/088; H10N 30/87

(57) ABSTRACT

An ultrasonic transducer device has an acoustic layer with a two-dimensional array of acoustically active elements, a first electrode layer on a first side of the acoustic layer and a second electrode layer on a second side of the acoustic layer. The first electrode layer and the second electrode layer have non-parallel electrodes that permit each acoustically active element in the two-dimensional array to be separately addressable by a controller. A series of kerfs separate adjacent acoustically active elements in the two-dimensional array of acoustically active elements of acoustically active elements, the series of kerfs being filled with a low dielectric, low acoustic impedance filler.

### TECHNICAL FIELD

This relates to an ultrasound transducer device, and in particular, an ultrasound transducer device with kerfs between acoustically active elements.

### BACKGROUND

Row-column arrays, also known as top orthogonal to bottom electrode arrays, are a type of sparse 2D array that is used to mitigate the challenge of complex wiring from such 2D arrays. In particular, bias-sensitive row-column arrays, including electrostrictive relaxor and CMUT row-column arrays, may be used to provide novel aperture encoding methods and permit readout from every element of the array using only row- and column addressing

U.S. Pat. No. 7,230,368 (Lukacs) entitled “Arrayed ultrasonic transducer” is an example a linear array of high-frequency transducers with air-filled kerfs that extend into a backing layer.

### SUMMARY

According to an aspect, there is provided an ultrasound transducer device, comprising: an acoustically active layer comprising an array of acoustically active elements in the acoustically active layer; a first electrode layer on a first side of the acoustically active layer and a second electrode layer on a second side of the acoustically active layer, each of the first electrode layer and the second electrode layer comprising a plurality of elongate electrodes. Each of the plurality of elongate electrodes of the first electrode layer and the second electrode layer have an electrical connection and wherein the elongate electrodes of the first electrode layer are angled relative to the first set of electrodes to permit row-column addressing within the array of acoustically active elements, A backing layer is adjacent to the second electrode layer. A first set of kerfs in the acoustically active layer that defines the array of acoustically active elements, the first set of kerfs comprising a low impedance filler that has a lower acoustic impedance than the acoustically active layer. A second set of kerfs are provided in the first electrode layer that defines the plurality of elongate electrodes in the first electrode layer, the second set of kerfs extending at least partly into the acoustically active layer. A third set of kerfs are provided in the second electrode layer that defines the plurality of elongate electrodes in the second electrode layer, the third set of kerfs extending at least partly into the backing layer, the acoustically active layer, or both the backing layer and the acoustically active layer.

In other aspects, the ultrasound transducer device may include one or more of the following elements: the array of acoustically active elements may be a two-dimensional array; at least a portion of the first electrode layer, the second electrode layer, and the array of acoustically active elements may be arranged in a top-orthogonal-to-bottom electrode configuration; at least a portion of the first electrode layer, the second electrode layer, and the array of acoustically active elements may be arranged in an aperiodic gridded array, such that a vector distance between any pairs of elements is unique; the second set of kerfs and the third set of kerfs may comprise a dielectric filler that has a higher electrical impedance than the plurality of elongate electrodes; wherein the dielectric filler may be atmospheric air or an inert gas; the array of acoustically active elements are may be in a grid pattern and the electrodes in the first electrode layer and the second electrode layer connect adjacent acoustically active elements at 45-degrees relative to the grid pattern; the acoustically active layer may comprise a piezoelectric material, an electrostrictive material, an electrostrictive relaxor material, micromachined membranes and gaps, or capacitive micromachined ultrasound transducers; the second set of kerfs and the third set of kerfs may extend into the acoustically active stack only in regions where the dielectric filler is present; the acoustically active material may be electrically coupled directly to each of the top electrode layer and the bottom electrode layer to minimize charging; there may be a stack of acoustically active layers, each acoustically active layer having a first electrode layer and a second electrode layer; thee may be one or more bias tees selectively connected to the electrical connection of one or more electrodes of the plurality of elongate electrodes; at least the acoustically active layer and the backing layer may be at least 50% transparent for one or more electromagnetic wavelengths; and there may be a housing that is a handheld housing, a wearable housing, a convex housing, or a concave housing.

According to another aspect, there is provided a method for manufacturing an ultrasound transducer device, comprising the steps of: mounting a bottom surface of a bulk material layer to a substrate; cutting into a top surface of the bulk material layer to create an array of pillars separated by a first set of kerfs that extend partly through a thickness of the bulk material layer, the bulk material layer comprising an acoustically active material; filling the first set of kerfs with a low impedance filler to form a composite layer, the low impedance filler having a lower acoustic impedance than the acoustically active material, and then lapping the top surface of the bulk material layer to form a composite layer in the bulk material layer; forming a first electrode layer on the top surface of the bulk material layer by patterning electrodes in the first electrode layer and providing an electrical connection for each electrode; forming a backing layer on an opposite side of the first electrode layer relative to the bulk material layer; removing the substrate from the bulk material layer and lapping the bottom surface of the bulk material until a bottom surface of the composite layer is exposed; forming a second electrode layer on the bottom surface of the composite layer by patterning electrodes in the first electrode layer and providing an electrical connection for each electrode; and connecting the first and second electrode layers to an electrical device.

In other aspects, the method for manufacture may include one or more of the following aspects, alone or in combination: the method may further comprise the step of adding one or more matching layers adjacent to the second electrode layer; patterning electrodes in the first electrode layer and the second electrode layer may comprise forming kerfs between adjacent electrodes that extend into the composite layer, the kerfs being filled with a dielectric material; the dielectric material may be atmospheric air or an inert gas; a backing layer is added adjacent to the first electrode layer or the second electrode layer such that air is trapped in the respective kerfs; and the method may further comprise the step of adding a shielding layer adjacent to the second electrode layer.

According to another aspect, there is provided an ultrasonic transducer device, comprising: an acoustic layer comprising a two-dimensional array of acoustically active elements; a first electrode layer on a first side of the acoustic layer and a second electrode layer on a second side of the acoustic layer, the first electrode layer and the second electrode layer comprising non-parallel electrodes that permit each acoustically active element in the two-dimensional array to be separately addressable by a controller; and a series of kerfs that separate adjacent acoustically active elements in the two-dimensional array of acoustically active elements of acoustically active elements, the series of kerfs being filled with a low dielectric, low acoustic impedance filler.

According to another aspect, there is provided an ultrasound transducer system with row-column-addressing and crosstalk-mitigating kerfs, comprising: a stack of layers, each layer having a top surface and an opposed bottom surface; at least one such layer in the stack comprising an acoustically active layer, a backing layer, and a plurality of electrodes above and below the acoustically active layer(s) and below the backing layer so as to define an array of acoustically active sub-elements arranged on a two-dimensional surface. Each electrode in the plurality of electrodes has a connection point in the outer perimeter of the array. Each acoustically active sub-element comprises volumes of acoustically active material, top electrodes and bottom electrodes. A first set of kerfs define a composite structure in one or more of the acoustically active layers, the first set of kerfs being filled with a dielectric material which has a lower acoustic impedance than the acoustically active layer. A second set of crosstalk mitigating kerfs extend partially into the acoustically active layer, the kerfs separating the plurality of bottom electrodes; this second set of kerfs filled with a dielectric filler. A third set of kerfs separate the plurality of top electrodes.

According to other aspects, the ultrasound transducer device may include one or more of the following elements, alone or in combination: a subset of electrodes and 2nd and 3rd set of kerfs may be patterned in a top-orthogonal-to-bottom electrode configuration; a subset of electrodes and 2nd and 3rd set of kerfs ma be patterned to comprise a multiplicity of elements, arranged in an aperiodic 2D gridded array, such that the vector distance between any pairs of elements is unique, and such that each element can be addressed with row- or column addressing; the first set of kerfs in the acoustically active layer may form a gridded composite structure with dielectric filler; a set of electrodes and 2nd and 3rd kerfs may be arranged so that the electrode traces connect composite pillars of acoustically active material 45-degrees relative to the composite grid patterns; the first, second and/or third kerfs may comprise a low dielectric material such as air or other inert gasses; the acoustically active layer may comprise a piezoelectric material, an electrostrictive material, an electrostrictive relaxor material, micromachined membranes and gaps, or capacitive micromachined ultrasound transducers; the 2nd and 3rd set of kerfs may be arranged such that they extend into the acoustically active stack only in regions where the dielectric filler is present; there may be no dielectric interface between the acoustically active material and top and bottom electrodes to minimize charging; there May be a plurality of acoustically active layers and a plurality of top and bottom electrode layers: one pair for each acoustically active layer; the row and column directions of electrodes of the row-column sub-array may align with the kerfs formed in a grid pattern in the composite or 45-degrees relative to the kerfs in the composite; at least one top or bottom electrode trace may connect a set of aperiodic 2D gridded array elements, such that the vector distance between any pair of elements (in the set of aperiodic 2D gridded array elements) is unique; there may be bias tees to create bias voltages in one or more electrodes relative to some other electrodes, while further allow transmit and receive signals to and from the elements of the array; the materials in the stack may have high transparency (>50%) for one or more electromagnetic wavelengths; the device may comprise housing for handheld or wearable uses, and the housing may be convex or concave.

According to an aspect, there is provided an integrated method for manufacturing an array comprising the following steps: using a laser or dicing saw to cut into a top surface of an acoustically active bulk material to create pillar structures followed by filling and lapping to form an 1-3 composite still attached to the bulk material; forming an electrode layer on the top surface of the composite (which will become the bottom electrode layer in the array) using sputtering, evaporation, or other process; patterning the electrodes using laser micromachining, lithography, or a scratch-dicing process; adding a dielectric backing material on the surface of the electrode opposite the composite (to become the back-side of the array) such as epoxy filled with dielectric particles, optionally first depositing or spreading a polymer layer; using a laser or dicing saw or similar, cutting into the backing layer, cutting to define top electrodes or cutting between already-defined electrodes into the acoustically active layer; creating backside connections to a printed circuit board, connector, or multiplicity of wires using wirebonding, laser sintering/welding, or laser micromachining after metallization; lapping the backing material flat; flipping the stack over, mounting the stack with backing layer attached to a lapping jig, and lapping the bulk acoustically active material to expose the composite; metalizing the now front side of the composite; patterning the metal to define the top electrodes; connecting the top electrodes to a printed circuit board, connector, or multiplicity of wires using wirebonding, laser sintering/welding, or laser micromachining after metallization.

According to other aspects, the method may include one or more of the following features, alone or in combination: there may be one or more matching layers added; there may be additional backing material added in such a way as to trap air in the 2nd set of kerfs; kerfs may be created by cutting into the composite; top and/or bottom electrodes may be laser machined while the active material or unlapped composite is mounted on a printed circuit board to further create connections to the printed circuit board; and an acoustic standoff dielectric layer and/or electrical shielding layer may be added.

According to another aspect, there is provided a transducer system comprising a row-column array comprised of a bias-voltage switchable piezoelectric or electrostrictive relaxor, the array comprising one or more sets of crosstalk-mitigating kerfs on the front or backside of the array, the kerfs comprising a low dielectric, low acoustic impedance filler, and each row and each column of the array connected to electronics, the electronics comprising biasing electronics, receiving electronics, or transmitting electronics, the transducer system further comprising a controller to control the biasing electronics or transmitting-receiving electronics.

In other aspects, the features described above may be combined together in any reasonable combination as will be recognized by those skilled in the art.

### BRIEF DESCRIPTION OF THE DRAWINGS

These and other features will become more apparent from the following description in which reference is made to the appended drawings, the drawings are for the purpose of illustration only and are not intended to be in any way limiting, wherein:

FIG. 1 is a top plan view of a transducer device with a row-column array.

FIG. 2 is a side elevation view in section of a transducer device that involves a row-column array.

FIG. 3 is a side elevation view in section of a bulk material layer bound to a glass carrier.

FIG. 4 is a side elevation view in section of the bulk material layer diced and filled with epoxy.

FIG. 5 is a side elevation view in section of a metal layer deposited on the bulk material layer.

FIG. 6 is a side elevation view in section of the metal layer formed into patterned electrodes.

FIG. 7 is a side elevation view in section of a 3D printed mold over the patterned electrodes filled with backing material.

FIG. 8 is a side elevation view in section of kerfs cut into the backing material and bulk material layer.

FIG. 9 is a side elevation view in section of kerfs cut into the bulk material layer.

FIGS. 10 and 11 are side elevation views in section of a PCB attached to the array.

FIGS. 12 and 13 are side elevation views in section of backing material added to the array.

FIG. 14 is a top plan view of the array with the PCB and backing material.

FIG. 15 is a side elevation view in section of the array with the PCB and backing material.

FIG. 16 is a side elevation view in section of the device with the carrier removed and a carrier installed on the opposite face of the device.

FIG. 17 is a top plan view side of the device with the carrier removed.

FIG. 18 is a top plan view of the completed device in a housing.

### DETAILED DESCRIPTION OF PREFERRED EMBODIMENTS

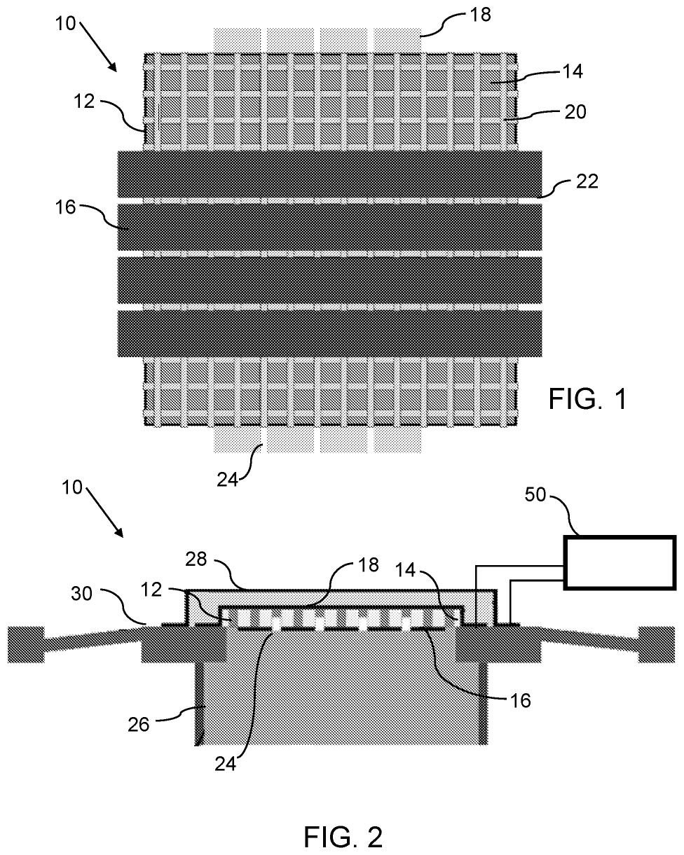

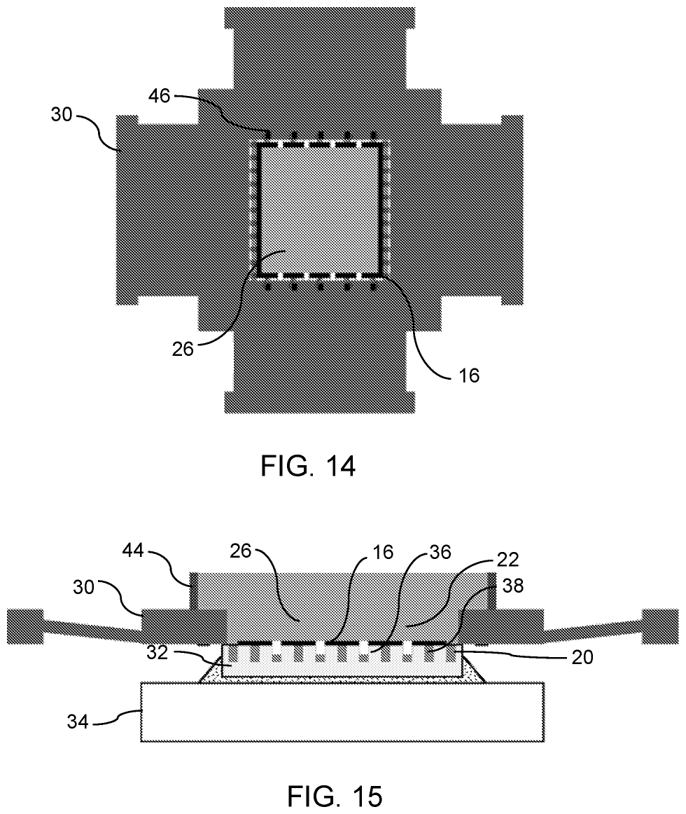

A transducer device, generally identified by reference numeral 10, will now be described with reference to FIG. 1 through 18.

There will now be described an architecture for row-column arrays that is designed to reduce the risk of various forms of crosstalk by creating kerfs that may be filled with low dielectric and low acoustic-impedance material, such as air, and a method for manufacturing such arrays.

Referring to FIGS. 1 and 2, the architecture is described in terms of a device 10 with a row-column array 12 that includes an ultrasonically-active composite material 14 that has top electrode strips 16 and bottom electrode strips 18. Top electrodes 16 are angled relative to bottom electrodes 18, where electrodes 16 and 18 may be in an orthogonal or near orthogonal configuration. Top electrodes 16 and bottom electrodes 18 combine with acoustically active elements 36 positioned therebetween to form a transducer element. Each electrode 16 and 18 may be connected separately to a controller, or connected as a group, such that individual transducer elements may be independently addressable, either in transmit or receive mode. The architecture also involves a first set of kerfs 20 that help define the composite material, and a second set of kerfs 22 that define a set of front-side (or back-side) electrodes 16 as is used in linear arrays. A third set of kerfs 24 may be used to define back-side (or front-side) electrodes 18, where the backside kerfs 24 extend further into the composite 14 and/or into the backing material 26. Electrodes 16 and 18 may be strips of material, or may be traces. In addition, while electrodes 16, 18 are described as being metal herein, it will be understood that other conductive materials may also be used Optionally, the second set of kerfs 22 may extend into the composite material 14 and the kerfs 22 and 24 on the frontside and backside may include a low acoustic impedance and/or low dielectric material. The kerfs 20, 22, 24 may be designed to reduce electrical and mechanical crosstalk between adjacent rows and/or adjacent columns of the array. The composite material 14 may include a piezoelectric, electrostrictive, electrostrictive relaxor materials, and/or an epoxy filler. The composite material 14 may also include micromachined membranes and gaps, or capacitive micromachined ultrasound transducers (not shown). Device 10 may also include a shielding layer 28, which may be a dielectric layer, or a conductive layer that is connected to a ground, and an interconnecting rigid-flex PCB (“printed circuit board”) 30.

While row-column array 12 is shown as a square grid, it will be understood that other designs may also be possible. For example, acoustic elements 36 may be arranged in an arranged in an aperiodic gridded array, such that a vector distance between any pairs of elements is unique. Row-column array 12 may also have a different design in different parts of the array. For example, certain parts of array 12 may be a square grid, and other parts may be an aperiodic grid.

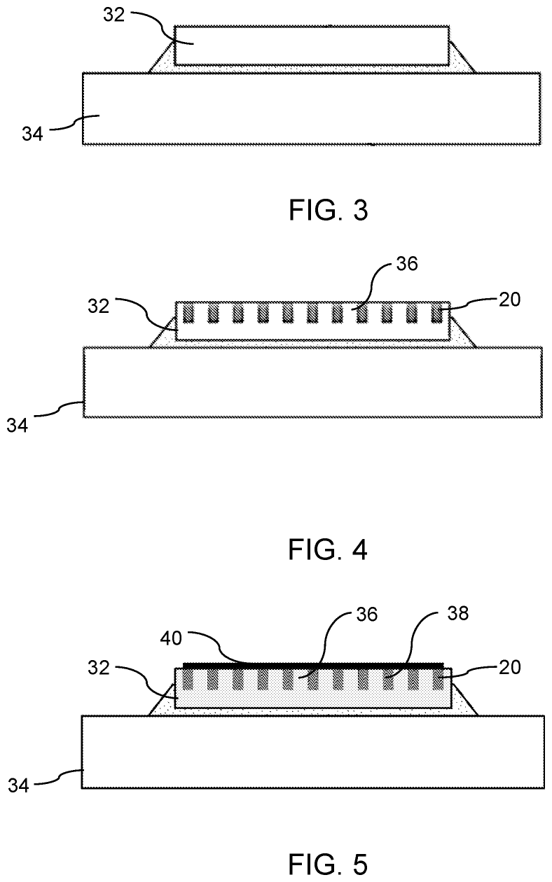

An example of a method of fabricating a device will be described with reference to FIG. 3 through 19.

First, referring to FIG. 3, a bulk material 32 such as an electrostrictive ceramic, piezoelectric ceramic or single-crystal piezoelectric material, is mounted on a carrier substrate 34, such as a glass disk. The mounting may be accomplished using an adhesive, such as crystal bond.

Second, referring to FIG. 4, bulk material 32 is cut into acoustically active elements 36, which may be described as pillars or posts, such as by using a dicing saw or laser micromachining tool, and may provide the beginnings of a 1-3 composite material 14. Referring to FIG. 5, the space between pillars 36 may be filled with an adhesive filler 38, for example an epoxy resin, which is then cured. The front-side may then be lapped with a lapping machine until posts 36 are exposed.

Next, referring to FIG. 5, a layer of metal 40 is deposited. Note that bulk material detachment is less of a risk at this stage, however there is a risk that cracking may occur in the bulk material 32 during the metal deposition. Some cracking may be acceptable provided that the metal surfaces 40 are contiguous. The risk of cracking may be reduced by cooling the array 12 slowly. To improve operations and minimize charging, the acoustically active material 14 may be electrically coupled directly to one or both electrode layer 16, 18.

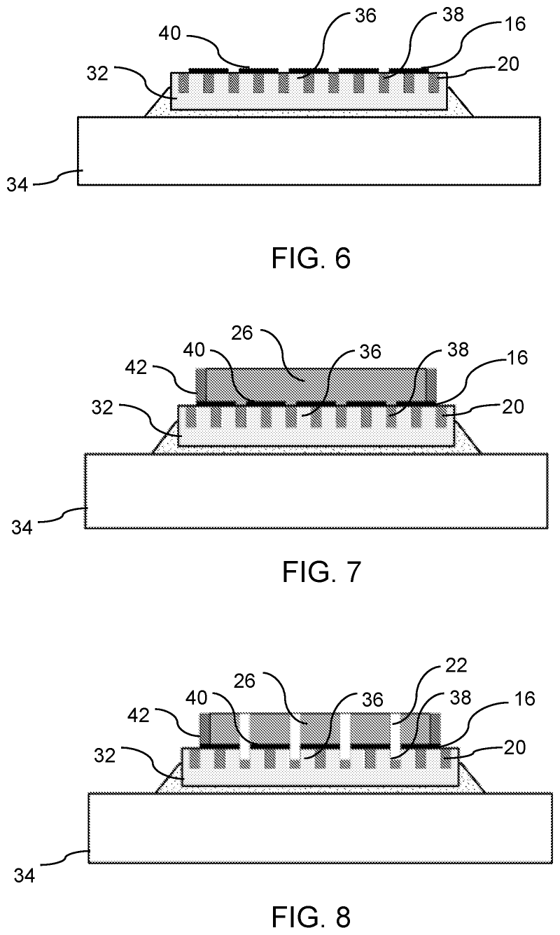

Referring to FIG. 6, the metal layer 40 may then be cut, such as by using a dicing saw or a laser micromachining system, to define separate electrodes 16 on the top surface of the composite 14. It has been found that a laser micromachining tool tends to produce less metal residue in the kerfs compared to dicing saws. The electrodes 16 may be pattered into simple strips or may be patterned with unique patterns, provided that the electrodes extend to the edge of the array 12 for readout from these edges.

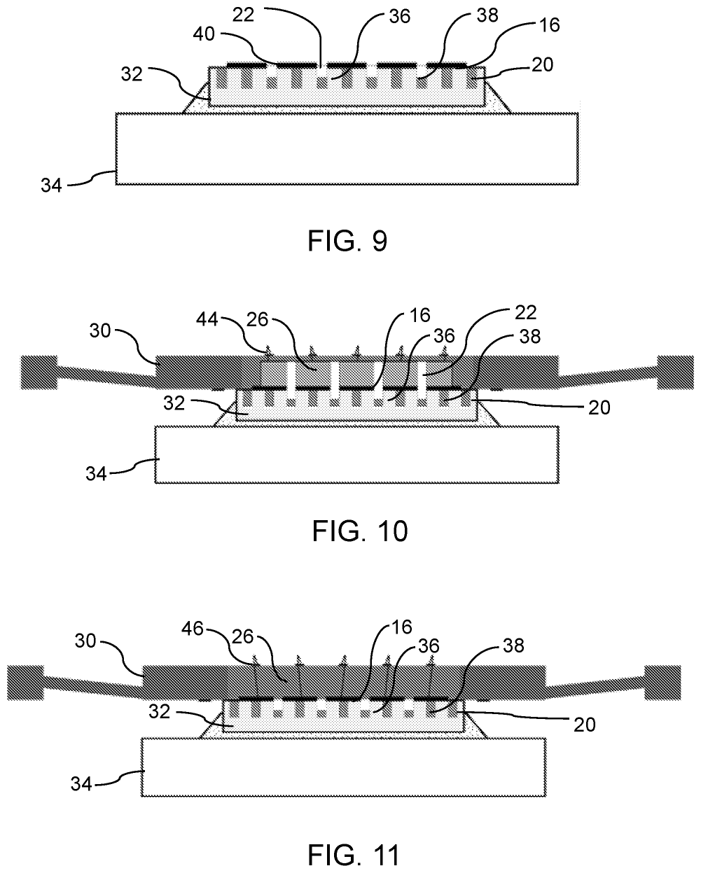

Next, referring to FIGS. 7 and 8, cross-talk mitigating kerfs 20 may be formed that extend into the backing material 26. Referring to FIG. 7, a thin layer of backing material 26 may be added within the confines of a barrier wall 42 adhered to the composite 14, where the exterior of barrier wall 42 may be used to preserve or protect metal bonding areas (not shown) for subsequent interconnection. Backing material 26 may then be lapped flat. Backing material 26 may be an epoxy, and may be loaded, such as with tungsten. Referring to FIG. 8, kerfs 22 may then be cut into backing material 26, which extend through backing material 26 down into composite 14. Alternatively, referring to FIG. 9, kerfs 22 may be cut into composite 14 prior to backing material 26 being added.

Whether or not cross-talk-mitigating kerfs are formed, the next steps are used key to avoiding previous problems of thin composites buckling or peeling off the carrier 34 during high-surface temperature steps such as metal deposition. Rather than flipping and remounting the composite 14 prior to lapping, the top side of the composite 14 is fixed, with remaining bulk material 32 below it, to a PCB 30, rigid-flex circuit board, flex PCB, or other device for electrical interconnection. The subsequent steps are done with this PCB or similar device affixed to the array 12.

Referring to FIGS. 10 and 11, a PCB 30 or similar device is then attached to the composite 14, such as by using an adhesive, for example an epoxy or cyanoacrylate. The top of the composite 14 is then electrically connected to PCB 30, such as by using wire-bonding 46 or other methods such as laser sintering, hot-bar-press, solder-stencil attachment, or the like. The top of the composite 14 may then be considered to be the backside of the array 12 and will subsequently be referred to as such. It will be understood that the reference to frontside and backside are relative terms and are used for convenience to describe the relative orientation. It will be understood that PCB 30 may be replaced with any suitable electrical component(s), such as connectors, or a multiplicity of wires connected using wirebonding, laser sintering/welding, or laser micromachining after metallization. For example, top and/or bottom electrodes 16, 18 may be machined while the active material 14 or unlapped composite is mounted on PCB 30 to further create connections to the printed circuit board.

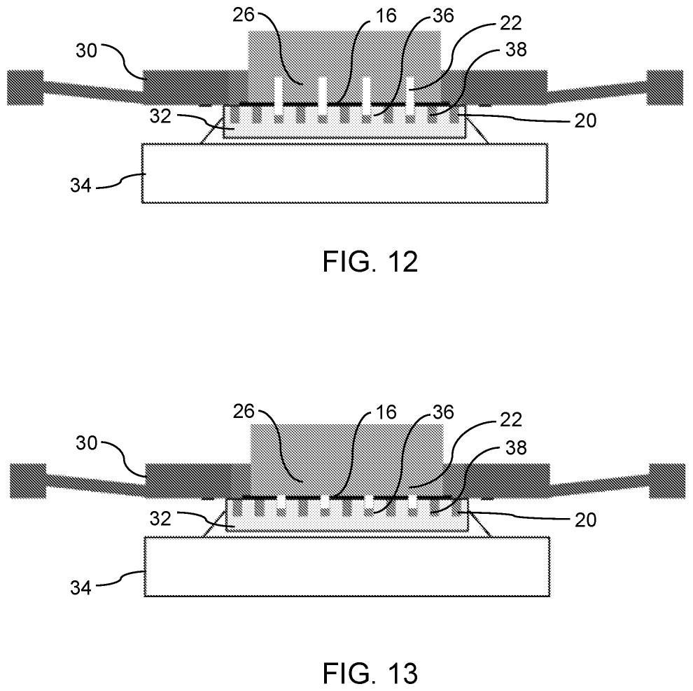

Next, referring to FIG. 12 through 14, an additional amount of backing material 26, such as a loaded epoxy or similar material, is added to the backside of the array 12, such as to preserve the kerfs 20, 22 present. If kerfs 20, 22 are filled with a low-dielectric low acoustic impedance filler, this may be done prior to adding this additional backing material 26, followed by an intermediate lapping step.

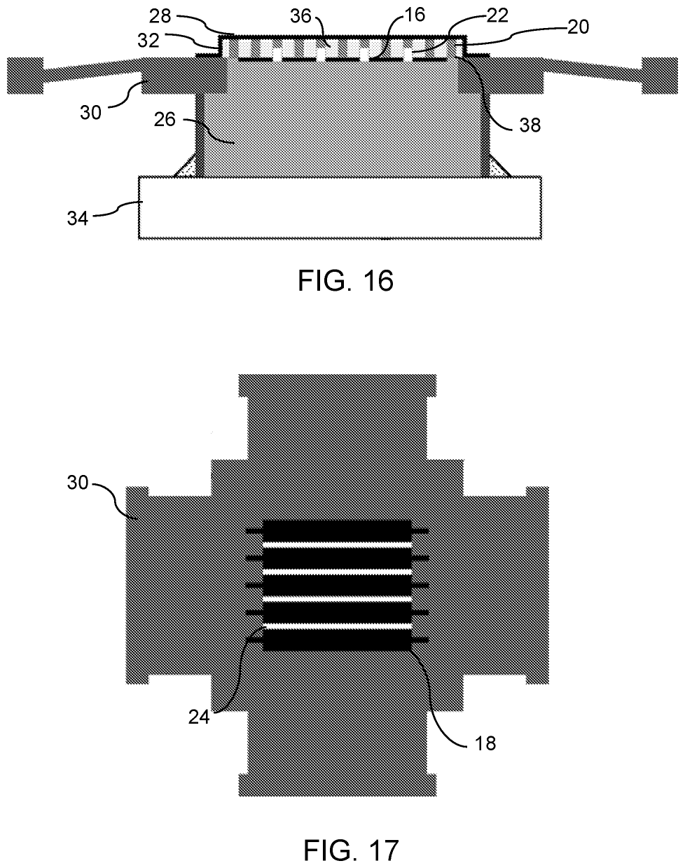

At this stage, the array 12 and the PCB 30 are rigidly mounted on the carrier substrate 34. Referring to FIG. 15, the backing material 26 may be applied within a barrier 44, such as a 3D printed mold, then lapped so it is flat and planar with the carrier substrate 34. Next, referring to FIG. 16, the array 12 is released from the carrier substrate 34 such as by heat or chemical means so as to soften the crystal bond or adhesive, and the backing material 26 is secured to another carrier substrate 48 such as by using an adhesive, for example crystal bond. The front-side of the array 12 is then lapped to a precision thickness to define the operating frequency of the array 12.

Referring to FIGS. 16 and 17, the front-side of the array 12 and associated PCB 30 (or similar interconnect device) may then be protected with cleanroom tape or a removable layer in regions where metal is not desired (not shown) and the protected array 12 may then be loaded into a deposition chamber for metal deposition. Because the array composite 14 is well secured to a thick backing layer 26, the risk of cracking or thermal buckling of the composite 14 is reduced. After metal deposition, laser or scratch dicing may be used to cut kerfs 24 and define the electrodes 18 on the front-side of the array 12. The kerfs 24 may extend into the composite material 14, similar to the kerfs 20, 22 formed in FIG. 8 or 9. The front-side of the array 14 may then be connected to the front-side of the PCB 30 using wire-bonding 46 or other interconnection method. Matching layers may be added before or after this interconnection step. Referring to FIGS. 2 and 19, an additional metal shielding layer 28 may be added on the arrays 14 and connected to ground or a protection circuit for added electrical safety.

While device 10 is shown with a single composite layer 14, there may also be multiple composite layers in a stack, each with its own pair of electrode layers. The stacked layers may be isolated or connected together, depending on the intended application. For example, the stacked layers may be separated by a shielding layer or a dielectric layer.

Once manufactured, referring to FIG. 2, acoustic transducer 10 may be connected to a controller to control its operation. Controller 50 may include or may be connected to electronics such as biasing electronics, receiving electronics, and/or transmitting electronics.

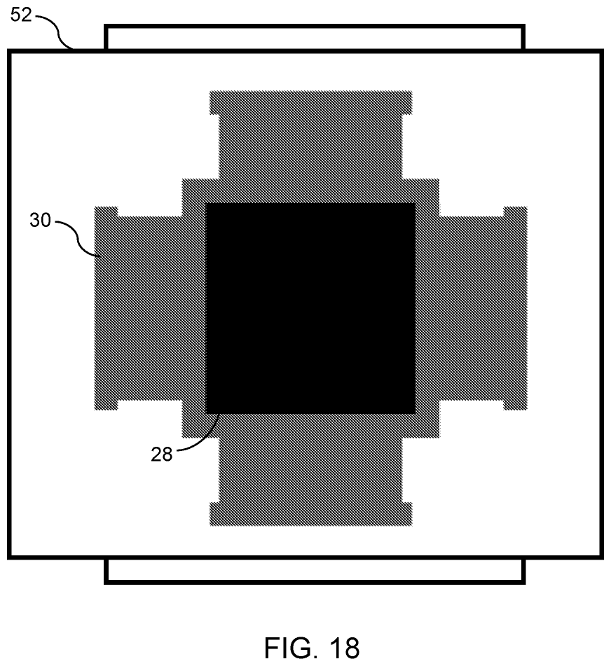

Referring to FIG. 18, acoustic device 10 may also be incorporated into a housing 52, which may be either handheld or wearable, which may be useful if device 10 is intended to be used as a sensor or detector. Housing 52 may be concave or convex (not shown) to accommodate an intended surface. Acoustic device 10 may also be made from transparent materials, such as materials that are 50% or more transparent to a certain wavelength or range of wavelengths, which may be useful if device 10 is used in combination with another sensor that detects or emits electromagnetic radiation.

To improve operation and reduce the risk of “cross-talk”, either electrical cross-talk between adjacent electrodes or acoustic cross-talk between acoustically active elements, kerfs 20, 22, 24 may be filled with an appropriately selected material, such as a low dielectric and/or low acoustic impedance material, depending on where the kerfs are located. In some cases, this may be an appropriately selected epoxy or similar material; in other cases, this may be air or an inert gas. Referring to FIG. 2, device 10 may be assembled such that air is trapped within kerfs 20, 22 and/or 24. In some cases, second and third kerfs 22, 24 may be localized to areas in which first kerfs 10 are filled with dielectric material.

It has been found that, during the fabrication process, the arrays may be prone to cracking due to the application of heat in some steps, such as metal deposition or lithography, and differences in the thermal expansion coefficients of materials while being bonded to a carrier substrate. It was also noticed that fabricating the array while mounted on a carrier using an adhesion layer such as a crystal bond may cause the adhesion layer to melt, which may cause other problems during later steps, such unwanted peeling of the array from the carrier, and/or air bubbles forming inside the adhesion layer that may cause the array to become unleveled and susceptible to detachment. Problems during fabrication may be exacerbated when the active element is thinner or has a larger area, which makes it more difficult to make larger-area arrays, which may be desirable when designing for finer lateral resolution in deep tissue that may be possible with a larger aperture size.

It has been found that by ensuring the layers are parallel, the stability and operation of the device may be improved. Preferably, the layers are parallel with a relatively high degree of accuracy. For example, the thicknesses of the various layers may be sufficiently parallel that the variation in the surfaces is within a predefined threshold. For example, the device 10 may be manufactured such that the bottom surface of the bulk material layer 32, the bottom surface of the composite layer 12, and/or the outer surface of the backing layer 26 are within a thickness variation. The predefined thickness is within 50 microns, or within 10 microns, or within 5 microns, or within 1 micron. This may be achieved, for example, by controlling the lapping steps to ensure proper thickness of the layers at the relevant stages of manufacture.

The presently described design and method of manufacture also addresses the risk of charging and cross-talk, which may result in image wire-target phantoms, and may cause images that are formed with the back side of the array to have more clutter than images formed from the front side.

To investigate the effect of cross-talk, a set of tests were performed in which one column was biased at a time and transmitted on that column while grounding all other rows and columns, then the transmitting element was electronically walked along the aperture by turning on the bias and transmission on a new element and grounding all other rows and columns (including the previously activated column). A metal plate was placed a short distance from the transducer in a water bath as a reflector. It was expected to see only one column transmitting and receiving in images of the channel data with only one column biased. Instead, many columns appeared to be sensitive to ultrasound reception when the backside was biased and transmitting. In contrast, when imaging with the front side of the array, crosstalk was much less significant. However, for both cases, a horizontal line was present, representing the capacitive coupling between elements, slightly stronger on the back side of the array due to the higher dielectric material.

It is believed that capacitive coupling between elements could not explain the crosstalk present except for a bit of a horizontal line present at the top of the banana-shaped channel data, mostly visible in the back-side imaging data. The rest of the banana-shaped signal was thought to arise from the time of flight differences associated with propagation paths from emitter to receiving elements. However, these would not be detected at all if the channels were not sensitive, which should have been the case. They should only be sensitive if a bias voltage is present. One possibility is that some stray electric fields may have been present inside the array, associated with potential differences between the biased column and other adjacent columns. However, if this were the case, it would affect the front-side image as well. The effects could also be attributed to residual polarization in the electrostrictive relaxor material itself, however, this would also affect the front-side image as well.

In addition to residual polarization, there may be some dielectric charging at play. The charging may be associated with particles or tiny air bubbles in the backing material, which may become charged in the presence of high electric fields. If such charging is present, it may have negative implications as elements may be sensitized that should not otherwise be sensitized. Alternatively, it could affect the level of biasing present between electrodes and alter the transmit and receive sensitivity.

Beyond these observations, there have been other observations associated with crosstalk. Electrical crosstalk may result from capacitive coupling between electrodes. Mechanical crosstalk may occur when an excited element propagates energy to its adjacent neighbouring elements. Such mechanical crosstalk may be mitigated by ensuring that the composite is cut in such a way as to ensure lateral mode frequencies are higher than the passband of the array. However, this may not completely eliminate such mechanical crosstalk.

The architecture and fabrication process discussed herein may be designed with air-filled, or low dielectric and low acoustic impedance material filled, kerfs that extend into the backing material, which may act to limit any dielectric particles between electrodes or elements and thus prevent charging. These air kerfs may further prove advantageous for minimizing capacitive coupling between elements and for minimizing mechanical crosstalk between elements.

The fabrication method discussed herein may be used to (1) mitigate or reduce the cracking or crystal bond bubbling due to mismatched thermal expansion of the bulk and/or composite material when on a carrier substrate and when subjected to processes involving appreciable heating; (2) mitigating or reducing the buckling of thin composites during heating; (3) facilitating a uniform thickness of the array, which becomes more difficult for larger-area arrays; (4) permitting the incorporation of cross-talk mitigating kerfs in the fabrication process; and (5) facilitating the metal adhesion for wire-bonding or other electrical interconnection strategies.

In the above fabrication procedure, some of the steps may be accomplished with the composite fixed to a PCB or similar device, which enables fabrication of large arrays without buckling or cracking, and facilitates the cross-talk mitigating kerfs.

In this patent document, the word “comprising” is used in its non-limiting sense to mean that items following the word are included, but items not specifically mentioned are not excluded. A reference to an element by the indefinite article “a” does not exclude the possibility that more than one of the elements is present, unless the context clearly requires that there be one and only one of the elements.

The scope of the following claims should not be limited by the preferred embodiments set forth in the examples above and in the drawings, but should be given the broadest interpretation consistent with the description as a whole.

What is claimed is:

1. An ultrasound transducer device, comprising:
an acoustically active layer comprising an array of acoustically active elements in the acoustically active layer;
a first electrode layer on a first side of the acoustically active layer and a second electrode layer on a second side of the acoustically active layer, each of the first electrode layer and the second electrode layer comprising a plurality of elongate electrodes, each of the plurality of elongate electrodes of the first electrode layer and the second electrode layer having an electrical connection and wherein the elongate electrodes of the first electrode layer are angled relative to the first set of electrodes to permit row-column addressing within the array of acoustically active elements;
a backing layer adjacent to the second electrode layer;
a first set of kerfs in the acoustically active layer that defines the array of acoustically active elements, the first set of kerfs comprising a low impedance filler that has a lower acoustic impedance than the acoustically active layer;
a second set of kerfs in the first electrode layer that defines the plurality of elongate electrodes in the first electrode layer, the second set of kerfs extending at least partly into the acoustically active layer; and
a third set of kerfs in the second electrode layer that defines the plurality of elongate electrodes in the second electrode layer, the third set of kerfs extending at least partly into the backing layer, the acoustically active layer, or both the backing layer and the acoustically active layer.

2. The ultrasound transducer device of claim 1, wherein the array of acoustically active elements is a two-dimensional array.

3. The ultrasound transducer device of claim 1, wherein at least a portion of the first electrode layer, the second electrode layer, and the array of acoustically active elements are arranged in a top-orthogonal-to-bottom electrode configuration.

4. The ultrasound transducer device of claim 1, wherein at least a portion of the first electrode layer, the second electrode layer, and the array of acoustically active elements are arranged in an aperiodic gridded array, such that a vector distance between any pairs of elements is unique.

5. The ultrasound transducer device of claim 1, wherein the second set of kerfs and the third set of kerfs comprise a dielectric filler that has a higher electrical impedance than the plurality of elongate electrodes.

6. The ultrasound transducer device of claim 5, wherein the dielectric filler is atmospheric air or an inert gas.

7. The ultrasound transducer device of claim 1, wherein the array of acoustically active elements are in a grid pattern and the electrodes in the first electrode layer and the second electrode layer connect adjacent acoustically active elements at 45-degrees relative to the grid pattern.

8. The ultrasound transducer device of claim 1, wherein the acoustically active layer comprising a piezoelectric material, an electrostrictive material, an electrostrictive relaxor material, micromachined membranes and gaps, or capacitive micromachined ultrasound transducers.

9. The ultrasound transducer device of claim 1, wherein the second set of kerfs and the third set of kerfs extend into the acoustically active stack only in regions where the dielectric filler is present.

10. The ultrasound transducer device of claim 1, comprising a stack of acoustically active layers, each acoustically active layer having a first electrode layer and a second electrode layer.

11. The ultrasound transducer device of claim 1, further comprising one or more bias tees selectively connected to the electrical connection of one or more electrodes of the plurality of elongate electrodes.

12. The ultrasound transducer device of claim 1, further comprising a housing that is a handheld housing, a wearable housing, a convex housing, or a concave housing.

13. A method for manufacturing an ultrasound transducer device, comprising the steps of:
mounting a bottom surface of a bulk material layer to a substrate;
cutting into a top surface of the bulk material layer to create an array of pillars separated by a first set of kerfs that extend partly through a thickness of the bulk material layer, the bulk material layer comprising an acoustically active material;
filling the first set of kerfs with a low impedance filler to form a composite layer, the low impedance filler having a lower acoustic impedance than the acoustically active material, and then lapping the top surface of the bulk material layer to form a composite layer in the bulk material layer;
forming a first electrode layer on the top surface of the bulk material layer by patterning electrodes in the first electrode layer and providing an electrical connection for each electrode to an electrical device;
forming a backing layer on an opposite side of the first electrode layer relative to the bulk material layer, the backing layer being formed such that an outer surface of the backing layer opposite the first electrode layer is substantially parallel to the bottom surface of the bulk material layer; removing the substrate from the bulk material layer and lapping the bottom surface of the bulk material until a bottom surface of the composite layer is exposed and is substantially parallel to the outer surface of the backing layer;
forming a second electrode layer on the bottom surface of the composite layer, patterning electrodes in the second electrode layer and providing an electrical connection for each electrode; and
connecting the second electrodes to an electrical device.

14. The method of claim 13 where the bottom surface of the bulk material layer, the bottom surface of the composite layer, and the outer surface of the backing layer are within a thickness variation of 50 microns or less.

15. The method of claim 13, further comprising the step of adding one or more matching layers adjacent to the second electrode layer.

16. The method of claim 13, wherein patterning electrodes in the first electrode layer and the second electrode layer comprise forming kerfs between adjacent electrodes that extend into the composite layer, the kerfs being filled with a dielectric material.

17. The method of claim 16, wherein the dielectric material is atmospheric air or an inert gas.

18. The method of claim 17, wherein a backing layer is added adjacent to the first electrode layer or the second electrode layer such that air is trapped in the respective kerfs.

19. The method of claim 13, further comprising the step of adding a shielding layer adjacent to the second electrode layer.

20. The method of claim 13 where the method of forming electrodes, forming kerfs, or connection to an electrical device comprises a laser micromachining process.

21. An ultrasonic transducer device, comprising:
an acoustic layer comprising a two-dimensional array of acoustically active elements;
a first electrode layer on a first side of the acoustic layer and a second electrode layer on a second side of the acoustic layer, the first electrode layer and the second electrode layer comprising non-parallel electrodes that permit each acoustically active element in the two-dimensional array to be separately addressable by a controller; and
a series of kerfs that separate adjacent acoustically active elements in the two-dimensional array of acoustically active elements of acoustically active elements, the series of kerfs being filled with a low dielectric, low acoustic impedance filler.
